(19) United States
(12) Patent Application Publication
(10) Pub. No.: US 2007/0257251 A1
(43) Pub. Date: Nov. 8, 2007

(54) ACENE COMPOSITIONS AND AN APPARATUS HAVING SUCH COMPOSITIONS

(75) Inventors: Sen Liu, Highland Park, NJ (US); Oleksander Sydorenko, Piscataway, NJ (US); Subramanian Vaidyanathan, Piscataway, NJ (US)

Correspondence Address: HITT GAINES, PC;ALCATEL-LUCENT, PO BOX 832570, RICHARDSON, TX, 75083, US

(73) Assignee: Lucent Technologies Inc., Murray Hill, NJ (US)

(21) Appl. No.: 11/381,771

(22) Filed: May 5, 2006

(51) Int. Cl. H01L 51/00; H01L 51/54; H01B 1/12

(52) U.S. Cl. 257/40; 257/E51.049; 528/396; 528/397; 528/423; 428/917; 428/690; 313/504; 427/66; 427/58

(57) ABSTRACT

An apparatus comprising a substrate and an organic semiconductor matrix being located over the substrate. The organic semiconductor matrix includes one of a polymer co-polymer or a stabilized pentacene. The polymer includes monomers of pentacene or a substituted pentacene. The stabilized pentacene is a substituted pentacene having a lower oxidation rate than pentacene.

### TECHNICAL FIELD OF THE INVENTION

The invention relates to new organic semiconductors and active devices that include such materials.

### BACKGROUND OF THE INVENTION

There is great interest in the development and use of organic electronic materials as alternatives to silicon-based semiconductors. Pentacene has among the highest mobilities of acenes and other organic molecules that may be used as organic semiconductors. As well known to those of ordinary skill in the art acenes are polycyclic aromatic hydrocarbons consisting of fused benzene rings in a rectilinear arrangement. The insolubility of acenes, such as pentacene, and their susceptibility to oxidation limit their application. Additionally, the low solubility means that relatively expensive vapor deposition techniques instead of solution processes must be used to form thin films of these compositions.

### SUMMARY OF THE INVENTION

One embodiment is a composition, comprising a polymer or a co-polymer of a plurality of monomers, each monomer being pentacene or a substituted pentacene.

Another embodiment is a composition comprising a plurality of molecules. Each molecule comprises two or more acenyl subunits that are covalently bonded to each other by a bridging subunit, the bridging subunit including an electron-withdrawing group comprising an oxadiazole group and a solubilizing group comprising a non-aromatic hydrocarbon.

Still another embodiment is an apparatus. The apparatus comprises a substrate and an organic semiconductor matrix located over the substrate. The organic semiconductor matrix includes one of a polymer, a co-polymer, or a stabilized pentacene. The polymer and the co-polymer include monomers of pentacene and/or substituted pentacene. The stabilized pentacene is a substituted pentacene having a lower oxidation rate than pentacene.

Yet another embodiment is a method that includes forming an organic semiconductor matrix over a substrate. The matrix includes one of the above-described polymer, co-polymer, or stabilized pentacene.

### BRIEF DESCRIPTION OF THE DRAWINGS

The invention is best understood from the following detailed description, when read with the accompanying FIGUREs. Various features may not be drawn to scale and may be arbitrarily increased or reduced in size for clarity of discussion. Reference is now made to the following descriptions taken in conjunction with the accompanying drawings, in which:

FIG. 1 presents a cross-sectional view of an exemplary embodiment of an apparatus comprising an OFET device;

FIG. 2 presents a cross-sectional view of an exemplary embodiment of an apparatus comprising an OLED device; and

FIG. 3 presents a flow diagram showing selected steps in an exemplary method of manufacture.

### DETAILED DESCRIPTION

While pentacene precursors that can be solution deposited as films and then converted to pentacene have been demonstrated, few attempts to stabilize the molecule have been made previously. Derivatization of pentacene with alkylsilyl groups has shown that the stability can be improved. This notwithstanding, the stability of these molecules, especially as thin films, is still poor. Moreover, thin films of pentacene are brittle and therefore are not ideally suited for use in flexible devices.

Presented are novel compositions of acene polymers and substituted acenes. The polymers are formed of monomers of acene or substituted acene. The polymers are expected to produce layers that are less brittle than layers made of the non-polymeric acene monomer. The acene polymers or substituted acenes can have electron-withdrawing substitutions. For that reason, the acene polymers or substituted acenes can be less susceptible to degradation via oxidation in air than the unsubstituted acene. The acene polymers or substituted acenes can also have solubilizing groups. Because these acene polymers or substituted acenes are more soluble in organic solvents, films comprising these molecules can be deposited using solution deposition processes. Consequently, an apparatus that includes these compositions is expected to have improved operating characteristics or longevity, or to be more easily fabricated.

One embodiment is a composition. The composition comprises a plurality of molecules, each molecule comprising two or more acenyl subunits. The molecules have a lower oxidation rate than an acene molecule having a same chemical composition as the acenyl subunit and measured under the same environmental conditions (e.g., under ambient light and air saturated solutions). For example, if the acenyl subunit comprises a pentacenyl group, then the molecule has a lower oxidation rate than pentacene. One of ordinary skill in the art would be familiar with conventional methods to measure the oxidation rate of organic molecules. For example, one could measure the rate of change in the ultraviolet or visible absorption spectrum of the acenyl-containing molecule over time and compare this to the rate of change of the parent acene molecule.

The plurality of molecules of the above described composition can be characterized by the general formula:
-(A-B)ₘ— (1)
where m≧1, “A” comprises the acenyl subunit: 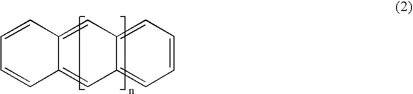
where n=1, 2, 3 . . . and “B” comprises the bridging subunit. As indicated by structure (1), the acenyl subunits and bridging subunit can be repeated m times to form an oligomer or polymer.

For example, some preferred embodiments of the composition comprise molecules having at least two acenyl subunits (e.g., m≧2) that are covalently bonded to each other by a bridging subunit. Preferably, the bridging subunit comprises at least one of an electron-withdrawing group and a solubilizing group. In other preferred embodiments the molecule is a polymer having at least 10 repeats of the acenyl subunit (e.g., m≧5).

The acenyl subunit can be any polycyclic aromatic hydrocarbon consisting of fused benzene rings in a rectilinear arrangement. The benzene rings can be derivatized. For example, one or more of the carbon atoms of the fused benzene rings can be substituted with halogen atoms, such as fluorine. As another example, one or both of the end benzene rings of the acenyl subunit can be derivatized by being fused to thiophene rings to form, e.g., a dithiophene acenyl subunit: 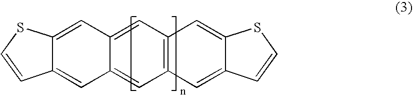
Some preferred dithiophene acenyl groups include anthradithiophene (e.g., n=1 in formula (3)) and pentadithiophene (e.g., n=3 in formula (3)).

For the purposes of the present invention, an electron-withdrawing group is any organic substitutent that causes the molecule to have a lowest unoccupied molecular orbital (LUMO) energy level that is lower than the LUMO energy level of the individual acene molecule. The electron withdrawing group, also know as electron acceptors, tend to withhold electrons through either inductive or resonance mechanisms. While not limiting the scope of the invention by theory, it is thought that lowering the LUMO energy level of the molecule makes it less susceptible to oxidation. One of ordinary skill in the art would be familiar with the conventional techniques to determine the LUMO energy level of molecules. Examples of such techniques include cyclic voltammetry, ultraviolet photoelectron spectroscopy, x-ray photoelectron spectroscopy, or combinations thereof. Non-limiting examples of some preferred electron withdrawing groups include oxadiazole groups, carbonyl groups and halogen-substituted rings, such as perfluorinated aromatic rings, trifluoro-substituted aromatic rings, or trifluoromethyl-substituted aromatic rings.

For the purposes of the present invention, a solubilizing group is defined as any organic substitutent that causes the molecule to have a solubility in an organic solvent that is greater than the solubility of the individual parent acene molecule in the same organic solvent. In some cases, the solubilizing group comprises a non-aromatic hydrocarbon group because the presence of an aromatic group is thought to decrease the solubility of the molecule. Suitable aliphatic hydrocarbon groups can include alkyl, alkoxyl, alkenyl, alkynyl, or cyclic aliphatic groups. The hydrocarbon group can be halogenated, and could be a branched or linear chain. In some preferred embodiments, the non-aromatic hydrocarbon group comprises an alkyl or alkoxy group having between 6 and 20 carbon atoms, and more preferably, between 8 and 16 carbon atoms. Non-limiting examples include linear or branched octyl, nonyl, decyl, undecyl and dodecyl alkyl groups.

The acenyl subunit can be substituted at any available carbon position in the fused benzene rings. In some cases the substitution chemically bonds a bridge subunit to any available carbon position in the fused benzene rings of the acenyl subunits. In some preferred embodiments, each of the acenyl subunits has an odd number of fused benzene rings (e.g., n=1, 3, 5, . . . ). An odd number of benzene rings is preferred in certain cases where it is desirable to introduce symmetric substituents into the acene ring. In addition, regioregular molecules are obtained when the acenyl subunits have an odd number of fused benzene rings and symmetric substitutions are made.

Consider, as an example, the case when the acenyl subunits comprise pentacenyl groups. The pentacenyl groups can have symmetric substitutions, e.g., in the 6 and 13 carbon positions. In other cases, the pentacenyl groups can be substituted in the 5 and 14 positions. Middle-carbon substitutions in the 6 and 13 positions of pentacenyl subunits (or e.g., the 5 and 10, or 7 and 16 positions of anthracenyl or heptacenyl subunits, respectively) are also advantage when the substituent is an electron-withdrawing group. Substitutions of an electron-withdrawing group in these positions facilitate the electron withdrawing group's effect on the electron density of the acenyl subunit. This, in turn, maximizes the effect of the electron withdrawing group on the LUMO energy level of the molecule.

In some cases, the bridging subunit is symmetrically attached to the acenyl subunits. Continuing with the same example of when the acenyl subunits comprise pentacenyl groups, the bridging subunit can be bonded to the 6 or 13 positions of pentacenyl groups to covalently bond two pentacenyl subunits together. Of course, asymmetric attachments, such as in the 5 or 14 positions of the pentacenyl groups, are also possible.

As noted above, the bridging subunit can comprise at least one of an electron-withdrawing group or a solubilizing group. In some preferred embodiments, however, the bridging subunit comprises both an electron-withdrawing group and a solubilizing group.

In some cases, the bridging subunit comprises an electron-withdrawing group with a solubilizing group chemically bonded thereto. Continuing with the example of when the molecule comprises pentacenyl subunits, the bridging subunit can comprise an electron-withdrawing group of phenyl-1,3,4-oxadiazole: 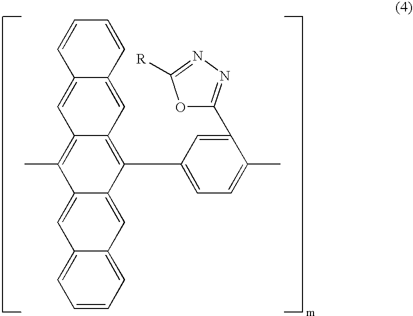
where m≧1, R is a solubilizing group, comprising, e.g., a non-aromatic hydrocarbon, such as discussed above. In this example the solubilizing group (R) is covalently bonded to the 5 position of the oxadiazole ring. In other embodiments, however, one or more solubilizing groups could be additionally or alternatively bonded to the phenyl ring of the phenyl-1,3,4-oxadiazole.

In other cases, the bridging subunit can further comprise a linker group that covalently bonds one or more electron-withdrawing group to at least one of the acenyl subunits. The linker group can comprise an aromatic or nonaromatic hydrocarbon. When the linker group comprises a nonaromatic hydrocarbon, the linker group can also be the solubilizing group. Continuing with the example of when the molecule comprises pentacenyl subunits, and the bridging subunit comprise an electron-withdrawing group of phenyl-1,3,4-oxadiazole. The molecule can also have a linker group which is the solubilizing group (R) of e.g., non-aromatic hydrocarbons (m≧1):

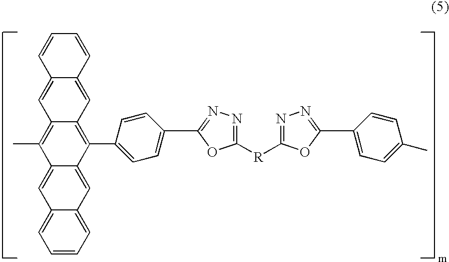

In still other cases, when the bridging subunit further comprises a linker group that comprises aromatic hydrocarbons, the solubilizing group can be attached to the electron-withdrawing group such as present for structure (3) above. Alternatively, the solubilizing group can be attached to the aromatic linker group. Consider again the example of where the molecule comprises pentacenyl subunits and the bridging subunit comprises an electron-withdrawing group of phenyl-1,3,4-oxadiazole. The molecule can comprise a linker group comprising aromatic hydrocarbons such as a stilbene, e.g., trans-1,2-diphenylethylene (m≧1): 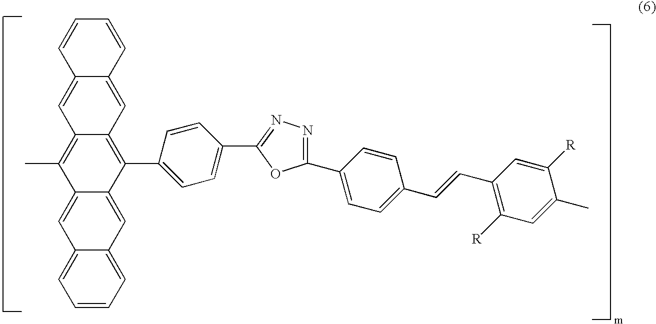
Of course, in other embodiments, the stilbene can be cis-1,2-diphenylethylene. As illustrated for structure (6), two of more solubilizing groups, R, can be attached to the linker group, for example, to a phenylene group of the stilbene linker group. One skilled in the art would appreciate that the solubilizing groups could be attached to different carbons of the linker groups or to both the linker group and the electron withdrawing group.

In some preferred embodiments, the pi-electrons of the electron-withdrawing group are conjugated to the pi-electrons of at least one of the acenyl subunits. For example, for structure (5), the conjugation is expected to extend from the pentacenyl subunit to the phenyl-1,3,4-oxadiazole that is bonded to that pentacenyl subunit. Extending pi-pi conjugation lengths in this manner is thought to increase the field effect mobility of the molecule when used as the semiconductor channel in an active device. For example, extending the conjugation length of anthracenyl or tetracenyl subunits are expected to significantly increase the mobility of the molecule as compared to anthracene or tetracene, respectively. Of course, as well understood by those skilled in the art, other factors, such as the morphology of the thin film semiconductor will also have important effects on mobility.

More preferably the electron-withdrawing group and linker group, if present, extends the conjugation between adjacent acenyl subunits. For example, as illustrated for structures (4) and (6), the conjugation is expected to extend from one pentacenyl subunit through the bridge subunit and to the second pentacenyl subunit. One of ordinary skill in the art would understand how to estimate the average conjugation length of the molecules, for example, based on their ultraviolet/visible and fluorescent spectroscopic properties.

Another embodiment is a composition that comprises a polymer of a plurality of monomers, each monomer being pentacene or a substituted pentacene. For instance, in the context of formulas (1) and (2), m≧2 and n=5. In some preferred embodiments, the polymer comprises at least 10 of the monomers. The monomers can be covalently joined together via any conventional bridging subunit, including, but not limited to, the bridging subunits presented above.

In some cases, at least some of the monomers can include a substituted pentacene. Here, a substituted pentacene has a substitution on one or more of the fused benzene rings of the pentacenyl group other than the substitutions needed to make a pentacene polymer. For example, one or more of the carbon atoms of the fused benzene rings can be bonded to a halogen atom substituent, such as fluorine. As another example, each substituted pentacene can include a pentacene unit and an electron-withdrawing group chemically bonded to the pentacene unit. The electron-withdrawing group need not participate in the bridging subunit, although, in some cases it may. In some preferred embodiments, the electron-withdrawing group comprises an oxadiazole group, such as 2-phenyl-1,3,4-oxadiazole. In other cases, a solubilizing group comprising a hydrocarbon chain is bonding to the oxadiazole group, for example, at the 5 position of the oxadiazole ring of the 2-phenyl-1,3,4-oxadiazole. More preferably, two oxadiazole groups are chemically bonded to the pentacene unit at the 6 and 13 positions. Exemplary molecules include 6,13-bis(2-phenyl-1,3,4-oxadiazole)pentacene and 5,14-bis(2-phenyl-1,3,4-oxadiazole)pentacene.

One of ordinary skill in the art would be familiar with methods to synthesize and purify the above-described molecules. Exemplary conventional synthetic reactions that could be adopted to synthesize these molecules are presented in: Anthony et al., J. Am. Chem. Soc. 2003, 123, 9482-83, and Vets et al., Synlett 2005, No. 2, 217-222, both of which are incorporated by reference in their entirety.

As an example, one possible synthetic route to produce structures (4), (5) and (6) involves lithiating a dibrominated precursor and reacting this with a pentacene quinone (e.g., 6,13 pentacenediquinone), by a nucleophilic addition. Reduction of the product of this reaction then gives the desired molecule. To form structure (4), for example, the dibrominated precursor can be a 2-(2, 5 dibromophenyl)-1,3,4-oxadiazole:

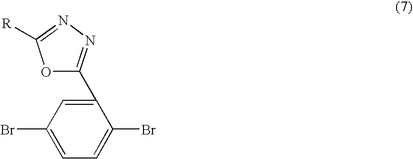

In analogous fashion, other dibrominated precursors can be used in the formation of structure (5): 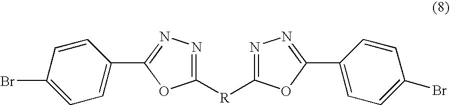
or in the formation of structure (6): 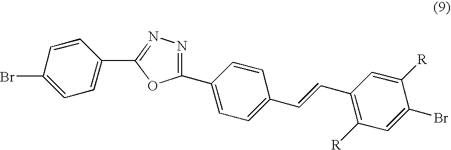
In some embodiments, it is possible to have more than one aromatic linking group with e.g., alkyl solublizing groups attached thereto per bridging unit. In still other embodiments, a mono-brominated precursor can be used to form a substituted pentacene. One of ordinary skill in the art would be familiar with the procedures and conditions to carry out the lithiation, nucleophilic addition, and reduction reactions.

Another embodiment is an apparatus. The apparatus comprises a matrix (e.g., a layer) composed of a plurality of any of the above-described molecules.

FIG. 1 presents cross-sectional views of an exemplary embodiment of an apparatus 100 that includes an active device such as an organic field effect transistor (OFET) 102. The apparatus 100 can be used in any number of applications, such as biosensors, integrated circuits, displays, logic devices and memory devices.

The OFET 102 comprises a substrate 105 and an organic semiconductor matrix 110, that functions as a channel, being located over the substrate 105. The organic semiconductor matrix 110 comprises one of a polymer or a stabilized pentacene.

The stabilized pentacene has a lower oxidation rate than pentacene. In preferred embodiments, the stabilized pentacene includes electron-withdrawing groups chemically bonded to a pentacene unit. For example, the stabilized pentacene can comprise 6,13-bis(2-phenyl-1,3,4-oxadiazole)pentacene or 6-(2-phenyl-1,3,4-oxadiazole)pentacene.

The polymer includes monomers of pentacene or a substituted pentacene. In some cases, each of the monomers comprise one pentacenyl subunit that is covalently bonded to a bridging subunit, the bridging subunit comprising at least one of an electron-withdrawing group or a one solubilizing group. As explained above, the bridging subunit can comprise both an electron-withdrawing group and a solubilizing group, or more than one of such groups. Exemplary polymers include at least 10 of the monomers. In certain preferred embodiments, the polymer has a lower oxidation rate than pentacene.

In some cases, the organic semiconductor matrix 110 has a half-life that is at least two times greater than an organic semiconductor channel made of pentacene, measured e.g., under ambient light conditions and in an air-saturated solution of the molecules. The half-life can be measured by any number of techniques sensitive to oxidation-induced changes in the molecules of the organic semiconductor 110. For example, one can determine a half-life by measuring the time dependent changes in the absorbance of a ultra-violet or visible absorption band of the polymer or stabilized pentacene. See e.g., Maliakal et al., Chem. Mater. 2004, 16, 4980-86, incorporated by reference herein in its entirety. This half-life can then be compared to the half-life of pentacene measured in the same manner and under the same environmental conditions.

In some preferred embodiments, organic semiconductor matrix 110 can be a p-type or n-type semiconductor. For example, when a p-type semiconductor is desired, the matrix can comprise molecules such as presented in the context of structures (1)-(6). When an n-type semiconductor is desired, the molecules of the organic semiconductor matrix 110 can comprise acenyl or bridging subunits that are substituted with one or more of a fluorine or fluorocarbon group. For example, the pentacene monomers or stabilized pentacene can be fluorine or fluorocarbon substituted.

The various components of the OFET 102 can comprise any conventional material well known to those skilled in the art. For example, the substrate 105 can be made of silicon or flexible organic materials such as plastics, for example polyethylene terephthalate (PET), polyethylene napthalate (PEN), or various polyamides.

The OFET 102 can further include first and second electrodes 115, 120 in contact with opposite ends 125, 130 of the organic semiconductor matrix 110. The source and drain electrodes 115, 120 can comprise e.g., gold or other electrically conductive metals or non-metals, such as electrically conductive polymers.

The OFET 102 shown in FIG. 1 can further includes a bottom gate 135 and a gate dielectric layer 140. The bottom gate 135 can comprise doped silicon. In other cases materials more conducive to forming a flexible device, such as indium tin oxide (ITO), can be used. Similarly, the gate dielectric 140 can comprise silicon dioxide, or more flexible materials, such as polymer dielectrics like polybutyl methacrylate (PBMA).

The OFET 102 presented in FIG. 1 is a top contact bottom gate OFET device. However, one of ordinary skill in the art would understand that the OFET 102 could have other conventional configurations, such as a bottom contact OFET device or top gate OFET devices, and the apparatus 100 could comprise a plurality of such devices.

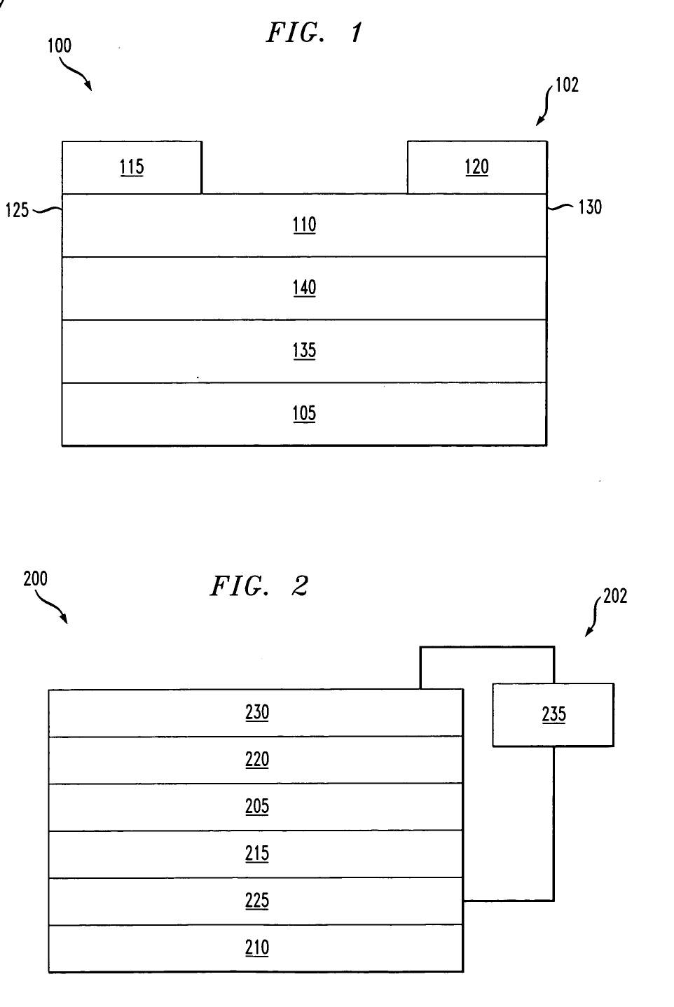

FIG. 2 presents a cross-sectional view of an exemplary embodiment of an apparatus 200 that includes an active device such as an organic light emitting diode (OLED) 202. One of ordinary skill in the art would readily appreciate how the below-described components could be configured to form an organic photovoltaic device instead of an OLED.

The OLED 202 shown in FIG. 2 has an organic semiconductor matrix 205 that functions as a light emitting junction. The organic semiconductor matrix 205 can comprise any of the above-described compositions. For instance, the organic semiconductor matrix 205 can include one of a polymer or a stabilized pentacene. In other instances, the organic semiconductor matrix 205 can include molecules comprising two or more acenyl subunits, which in some cases are covalently linked together with a bridging subunit.

The OLED 202 as illustrated in FIG. 2 can further include a number of conventional components such as a substrate 210, hole injection layer 215, electron transport layer 220, and cathode and anode 225, 230 electrically connected to a voltage source 235. These components can comprise any conventional material well known to those skilled in the art. For example, the substrate 210 can comprise glass, the hole injection layer 215 can comprise polyethylenedioxythiophene: poly(styrenesulfonate), the electron transport layer 220 can comprise tris-8-hydroxyquinoline aluminum and the cathode and anode 230, 225 can comprise conductive materials, such as aluminum or ITO respectively.

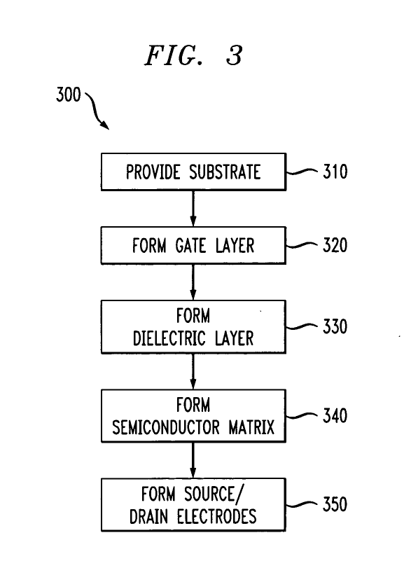

Another embodiment is a method of manufacture. The method of manufacture can be used to fabricate any of the above-described apparatuses. FIG. 3 presents a flow diagram showing selected steps in an exemplary method of manufacturing a device.

A substrate is provided in step 310. The substrate can include any conventional material, including the materials discussed above in the context of FIGS. 1-2. The substrate can also include device component layers such as a bottom gate 135 and dielectric layer 140 in the case of OFET devices 102, such as illustrated in FIG. 1. Alternatively the substrate can comprise a hole injection layer 215 and cathode 225 in the case of an OLED 202, as illustrated in FIG. 2. In some embodiments of the method, the substrate comprises glass upon which are successively formed, in step 320, a gate electrode comprising physical vapor deposited ITO, and an insulating layer, in step 330, comprising spin-coated PBMA. Alternatively, the substrate can comprise a silicon layer implanted with n- or p-type dopants, followed by a thermally grown SiO₂ dielectric layer, in steps 320 and 330, respectively.

In step 340, an organic semiconductor matrix is formed over the substrate. The matrix can be a thin film semiconductor layer in OFET devices or a light-emitting layer in OLED devices. The molecules can comprise any of the above-described embodiments of the compositions.

In some instances, forming the matrix comprises evaporating molecules of the organic semiconductor matrix onto the substrate. This is expected to be the case when the molecules of the matrix do not have a solubilizing group. Preferred evaporating conditions include pressures of about 1×10⁻⁵ Torr or less. In some cases, organic semiconductor matrices formed via evaporation have thicknesses ranging from about 50 to about 100 nanometers.

In some preferred embodiments, forming the matrix comprises depositing a solution of the organic semiconductor matrix onto the substrate. This is expected to be the case when the molecules of the matrix do have a solubilizing group. Any number of conventional solution processing techniques can be used to deposit the solution. Examples include drop-casting, spin-casting, dip-coating or liquid-jet-printing.

In step 350, source and drain electrodes are formed on the organic semiconductor matrix using conventional procedures. In some cases, for example, gold source and drain electrodes are deposited on the layer using a shadow mask. Of course, alternative steps, well known to those of ordinary skill in the art, would be followed to deposit the anode and hole injection layers to form an OLED device such as illustrated in FIG. 2. Also, further steps, well-known to those skilled in the art, could be performed to form an operative device.

Although the embodiments have been described in detail, those of ordinary skill in the art should understand that they could make various changes, substitutions and alterations herein without departing from the scope of the invention.

What is claimed is:

1. A composition, comprising:
a polymer or a co-polymer of a plurality of monomers, each monomer being pentacene or a substituted pentacene.

2. The composition of claim 1, wherein the polymer includes at least 10 of the monomers.

3. The composition of claim 1, wherein some of the monomers include a substituted pentacene, each substituted pentacene including a pentacene unit and an electron-withdrawing group chemically bonded to the pentacene unit.

4. A composition, comprising:
a plurality of molecules each comprising two or more acenyl subunits that are covalently bonded to each other by a bridging subunit, the bridging subunit including an electron-withdrawing group comprising an oxadiazole group and a solubilizing group comprising a non-aromatic hydrocarbon.

5. The composition of claim 4, wherein the acenyl subunits both comprise a pentacenyl or a substituted pentacenyl group.

6. The composition of claim 4, wherein the molecule is a polymer having at least 10 repeats of the acenyl subunit.

7. The composition of claim 4, wherein the non-aromatic hydrocarbon comprises alkyl or alkoxy group having between 6 and 20 carbon atoms.

8. The composition of claim 4, wherein the oxadiazole group comprises phenyl 1,3,4-oxadiazole.

9. An apparatus, comprising:
a substrate; and
an organic semiconductor matrix being located over the substrate and including one of a polymer, co-polymer or a stabilized pentacene; and
wherein the polymer and co-polymer include monomers of pentacene and/or a substituted pentacene; and
wherein the stabilized pentacene is a substituted pentacene having a lower oxidation rate than pentacene.

10. The apparatus of claim 9, wherein the stabilized pentacene includes electron-withdrawing groups chemically bonded to a pentacene unit.

11. The apparatus of claim 9, wherein the polymer includes at least 10 of the monomers.

12. The apparatus of claim 9, wherein the polymer has a lower oxidation rate than pentacene.

13. The apparatus of claim 9, wherein each of the monomers comprise one pentacenyl subunit that is covalently bonded to a bridging subunit, the bridging subunit comprising at least one electron-withdrawing group.

14. The apparatus of claim 9, wherein each of the monomers comprise one pentacenyl subunit that is covalently bonded to a bridging subunit, the bridging subunit having at least one solubilizing group.

15. The apparatus of claim 9, wherein the apparatus includes an organic light emitting diode.

16. The apparatus of claim 9, wherein the apparatus includes an organic field effect transistor.

17. A method of manufacture, comprising,
forming an organic semiconductor matrix over a substrate, said organic semiconductor matrix including one of a polymer, copolymer and a stabilized pentacene; and
wherein the polymer and copolymer includes monomers of pentacene or substituted pentacene, and the stabilized pentacene is a substituted pentacene having a lower oxidation rate than pentacene.

18. The method of claim 17, wherein each of the monomers comprise one pentacenyl subunit that is covalently bonded to a bridging subunit, the bridging subunit comprising at least one an electron-withdrawing group or solubilizing group.

19. The method of claim 17, wherein forming said matrix comprises evaporating molecules of said organic semiconductor matrix onto said substrate.

20. The method of claim 17, wherein forming said matrix comprises depositing a solution of said organic semiconductor matrix onto said substrate.
